(19) United States
(12) Patent Application Publication
(10) Pub. No.: US 2006/0171233 A1
(43) Pub. Date: Aug. 3, 2006

(54) Near pad ordering logic

(76) Inventors: Khaled Fekih-Romdhane, Houston, TX (US); Skip Shizhen Liu, Clackamas, OR (US)

Correspondence Address: PATTERSON & SHERIDAN, LLP;Gero McClellan / Infineon Technologies, 3040 POST OAK BLVD.,, SUITE 1500, HOUSTON, TX, 77056, US

(21) Appl. No.: 11/037,579

(22) Filed: Jan. 18, 2005

(51) Int. Cl. G11C 8/00; G06F 12/06

(52) U.S. Cl. 365/230.03; 711/5

(57) ABSTRACT

Techniques and circuitry that support switching operations required to exchange data between memory arrays and external data pads are provided. In a write path, such switching operations may include latching in and assembling a number of bits sequentially received over a single data pad, reordering those bits based on a type of access mode (e.g., interleaved or sequential), and performing scrambling operations based on chip organization (e.g., x4, x8, or x16) a bank location being accessed. Similar operations may be performed (in reverse order) in a read path, to assemble data to be read out of a device.

### BACKGROUND OF THE INVENTION

1. Field of the Invention

The invention generally relates to accessing memory devices and, more particularly, to accessing doubled data rate (DDR) dynamic random access memory (DRAM) devices, such as DDR-II type DRAM devices.

2. Description of the Related Art

The evolution of sub-micron CMOS technology has resulted in an increasing demand for high-speed semiconductor memory devices, such as dynamic random access memory (DRAM) devices, pseudo static random access memory (PSRAM) devices, and the like. Herein, such memory devices are collectively referred to as DRAM devices.

Some types of DRAM devices have a synchronous interface, generally meaning that data is written to and read from the devices in conjunction with a clock pulse. Early synchronous DRAM (SDRAM) devices transferred a single bit of data per clock cycle (e.g., on a rising edge) and are appropriately referred to as single data rate (SDR) SDRAM devices. Later developed double-data rate (DDR) SDRAM devices included input/output (I/O) buffers that transfer a bit of data on both rising and falling edges of the clock signal, thereby doubling the effective data transfer rate. Still other types of SDRAM devices, referred to as DDR-II SDRAM devices, transfer two bits of data on each clock edge, typically by operating the I/O buffers at twice the frequency of the clock signal, again doubling the data transfer rate (to 4× the SDR data transfer rate).

Unfortunately, as memory speeds increase, operating the I/O buffers and processing the data at twice the clock frequency presents a number of challenges. For example, modern SDRAM devices support a number of different data transition modes (e.g., interleaved or sequential burst modes) that require data to be reordered before it is written to or after it is read from the memory array. Further, for various reasons (e.g., geometry, yield, and speed optimizations) these devices often have physical memory topologies employing “scrambling” techniques where logically adjacent addresses and/or data are not physically adjacent. This data reordering and scrambling affects when and how data is passed between data pads and a memory array and typically requires complex switching logic.

Because of this complexity, conventional data path switching logic is typically designed by synthesis, which generally refers to the process of converting a design from a high-level design language (e.g., VHDL) into actual gates. Unfortunately, synthesis design has shortcomings. As an example, it typically puts all the combination logic together resulting in more gate delay and larger mask area, which hurts both performance and density. Furthermore, timing glitches and unnecessary switching operations in these designs often degrade speed performance and increase power consumption. These timing issues become more problematic as clock frequencies increase. In addition, the typically unstructured nature of logic designed by syntheses does not promote reuse, for example, across device family members with different organizations (e.g., x4, x8, and x16) or within a single device that supports different organizations.

Accordingly, what is needed is a flexible data path logic design capable of supporting switching operations required to transfer data between memory arrays and external data pads.

### SUMMARY OF THE INVENTION

Embodiments of the present invention generally provide methods and devices for efficient transfer of data between data pads and memory arrays.

One embodiment provides a memory device generally including one or more memory arrays, a plurality of data pads, an input/output (I/O) buffers stage, and reordering logic. The I/O buffer stage has pad logic for receiving bits of data to be written to the memory arrays and outputting bits of data sequentially on the plurality of pads, wherein N bits of data are received or transferred in a single cycle of an external clock signal. The reordering logic is driven by a core clock signal having a lower frequency than the external clock signal and configured to reorder the N bits of data received on each data pad based at least in part on a burst transfer type prior to writing the N bits to the one or more memory arrays or prior to outputting the N bits sequentially on the plurality of pads.

Another embodiment provides a memory device generally including one or more memory arrays, a plurality of data pads, and a pipelined data path. The pipelined data path is configured for transferring data between the one or more memory arrays and the plurality of pads comprising an input/output (I/O) buffer stage with pad logic for buffering bits of data exchanged sequentially between the data pads and an external device in conjunction with a data clock signal and reordering logic for reordering bits of data received by or to be output by the pad logic in conjunction with a core clock signal having a lower frequency than the data clock signal.

Another embodiment provides a memory device capable of transferring multiple bits on each of a plurality of data pads in a single external clock signal generally including one or more memory arrays and reordering logic. The reordering logic is driven by a core clock signal having a frequency less than the external clock signal and configured to reorder bits of data received sequentially on the data pads to be written to the memory arrays and to reorder bits of data read from the memory arrays to be output sequentially on the data pads.

Another embodiment provides a method of exchanging data with a memory device. The method generally includes receiving N bits of data on each of a plurality of data pads within a single cycle of an external clock signal and reordering the N bits of data in conjunction with an internal core clock signal having a lower frequency than the external clock signal.

Another embodiment provides a method of exchanging data between data pads and one or more memory arrays. The method generally includes, during a write operation, generating, from an external clock signal, a core clock signal having a lower frequency than the external clock signal, sequentially receiving multiple bits of data to be written to the memory arrays on the data pads in a single cycle of the external clock signal, and reordering, in conjunction with the core clock signal, the sequentially received bits of data prior to being written to the memory arrays or prior to being output on the data pads.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a dynamic random access memory (DRAM) device in accordance with embodiments of the present invention;

FIG. 2 illustrates an exemplary DRAM data path in accordance with embodiments of the present invention;

FIG. 3 illustrate exemplary operations for writing data to and reading data from memory arrays, respectively;

FIGS. 4A and 4B illustrate an exemplary block diagram of near pad ordering logic and corresponding truth table, respectively;

FIGS. 5A and 5B illustrate an exemplary write path ordering switching matrix and corresponding truth table, respectively;

FIGS. 6A and 6B illustrate an exemplary read path ordering switching matrix and corresponding truth table, respectively;

FIGS. 7A and 7B illustrate example settings for the switching matrices illustrated in FIGS. 5A and 6A, respectively;

FIG. 8 illustrates an exemplary block diagram of intelligent array switching logic, in accordance with embodiments the present invention;

FIG. 9 illustrates an exemplary switch arrangement and signal routing for the intelligent array switching logic shown in FIG. 8;

FIGS. 10A and 10B illustrate a single stage of the switch arrangement shown in FIG. 9 and corresponding truth table, respectively;

FIG. 11 illustrates switch settings of the single stage shown in FIG. 10A for a x16 memory organization;

FIGS. 12A and 12B illustrate switch settings of the single stage shown in FIG. 10A for a x8 memory organization; and

FIGS. 13A-D illustrate switch settings of the single stage shown in FIG. 10A for a x4 memory organization.

### DETAILED DESCRIPTION OF THE PREFERRED EMBODIMENT

Embodiments of the invention generally provide techniques and circuitry that support switching operations required to transfer data between memory arrays/banks and external data pads. In a write path, such switching operations may include latching in and assembling a number of bits sequentially received over a single data pad, reordering those bits based on a particular type of access mode (e.g., interleaved or sequential, even/odd), and performing scrambling operations based on chip organization (e.g., x4, x8, or x16) a bank location being accessed. Similar operations may be performed (in reverse order) in a read path, to prepare and assemble data to be read out of a device.

By distributing these switching operations among different logic blocks in the data path, only a portion of the operations (e.g., latching in the data) can be performed at the data clock frequency, while the remaining operations (e.g., ordering and scrambling) may be performed at a lower frequency (e.g., ½ the external clock frequency). In addition, by dividing these switching operations, the operations may be performed in parallel (e.g., in a pipelined manner), rather than placing all the complex decoding at one complex block in a serial fashion. As a result, this distributed logic approach may help reduce the speed bottleneck at the data path level and improve (DDR-II SDRAM) device performance.

### An Exemplary Memory Device with Simplified Pad Logic

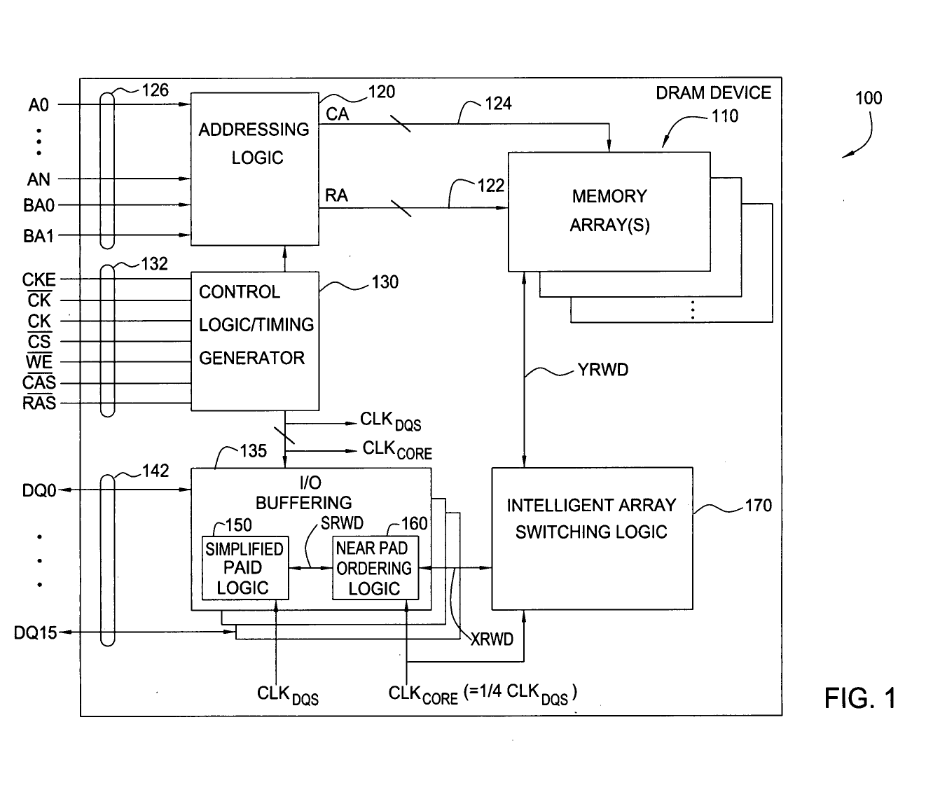

FIG. 1 illustrates an exemplary memory device 100 (e.g., a DRAM device) utilizing data path logic design in accordance with one embodiment of the present invention, to access data stored in one or more memory arrays (or banks) 110.

As illustrated, the device 100 may include control logic 130 to receive a set of control signals 132 to access (e.g., read, write, or refresh) data stored in the arrays 110 at locations specified by a set of address signals 126. The address signals 126 may be latched in response to signals 132 and converted into row address signals (RA) 122 and column address signals (CA) 124 used to access individual cells in the arrays 110 by addressing logic 120.

Data presented as data signals (DQ0-DQ15) 142 read from and written to the arrays 110 may be transferred between external data pads and the arrays 110 via I/O buffering logic 135. As previously described, this transfer of data may require a number of switching operations, including assembling a number of sequentially received bits, reordering those bits based on a type of access mode (e.g., interleaved or sequential, even/odd), and performing scrambling operations based on chip organization (e.g., x4, x8, or x16) and the physical location (e.g., a particular bank or partition within a bank) of the data being accessed. While conventional systems may utilize a single complex logic block to this perform all of these switching operations, embodiments of the present invention may distribute the operations between multiple logic blocks.

For some embodiments, these logic blocks may include simplified pad logic 150, near pad ordering logic 160, and intelligent array switching logic 170. The simplified pad logic 150 and near pad ordering logic 160 may be integrated within the I/O buffering logic 135. As illustrated, for some embodiments, only the simplified pad logic 150 may be operated at the data clock frequency (typically twice the external clock frequency for DDR-II), while the near pad ordering logic 160 and intelligent array switching logic 170 may be operated at a slower memory core frequency (typically ½ the external clock frequency).

In general, during a write operation, the simplified pad logic 150 is responsible only for receiving data bits presented serially on external pads and presenting those data bits in parallel (in the order received) to the near pad ordering logic 160. The near pad ordering logic 160 is responsible for (re)ordering these bits based on the particular access mode and presenting the ordered bits to the intelligent array switching logic 170. The intelligent array switching logic 170 is responsible for performing a 1:1 data scrambling function, writing data on one set of data lines to the arrays into memory bank array through another set of data lines. As will be described in greater detail below, exactly how the data is scrambled may be determined by a specified chip organization (e.g., x4, x8 and x16) and a particular bank partition being accessed. These components operate in a reverse manner along the read path (e.g., when transferring data in a read operation).

### Read and Write Data Paths

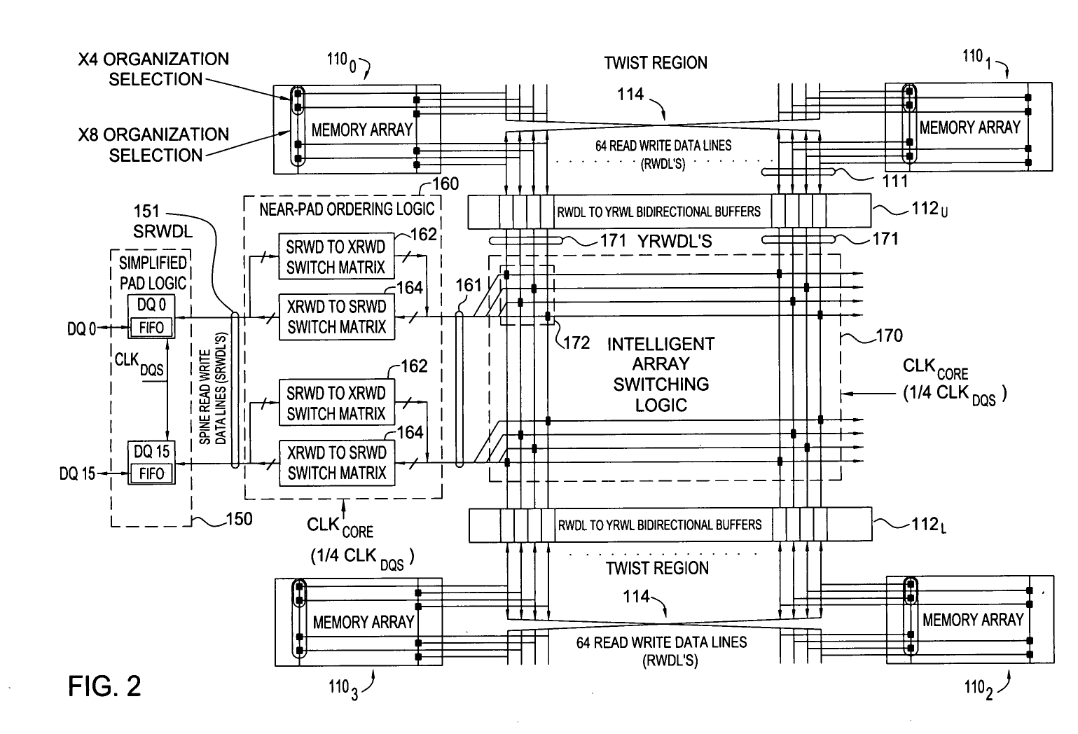

The cooperative functions of the simplified pad logic 150, near pad ordering logic 160, and intelligent array switching logic 170 may be described with reference to FIG. 2, which shows an exemplary read/write data path, in accordance with embodiments of the present invention. To facilitate understanding, the write and read paths will be described separately, beginning with the write path.

As illustrated, the simplified pad logic 150 may include any suitable arrangement of components, such as first in first out (FIFO) latching buffers, configured to receive and assemble a number of data bits presented serially on an external pad. Each external data pad may have its own corresponding stage 152, driven by the data clock. As previously described, in a DDR-II DRAM device, data may be transferred on rising and falling edges of the data clock, such that four bits of data may be latched in each external clock cycle.

Once four bits are latched in (e.g., each external clock cycle) by each stage 151, these bits may be transferred to the near pad ordering logic 160 in parallel, in the order in which they were received, for possible reordering based on the type of access mode. In other words, the simplified pad logic 150 merely has to latch in data signals without having to perform any ordering or scrambling based on address signals, which may reduce the chances of noise glitches as the data signals transition at the (higher) data clock frequency. This approach may also simplify signal routing, as address signals necessary for ordering do not need to be routed to the pad logic.

As illustrated, data may be transferred between the simplified pad logic 150 and the near pad ordering logic 160 via a bus of data lines referred to as spine read/write data (SRWD) lines 151. Assuming a total of 16 external data pads DQ<15:0>, there will be 64 total SRWD lines 151 (e.g., the pad ordering logic performs a 4:1 fetch for each data pad) for a DDR-II device (32 for a DDR-I device and 128 for DDR-III). While the simplified pad logic 150 operates at the higher data clock frequency, because data is transferred only after four bits are received sequentially, the pad ordering logic 160 may be operated at the lower memory core clock (CLK_{CORE}) frequency.

As illustrated, the near pad ordering logic 160 may include, for each corresponding data pad, an arrangement of switches (herein referred to as a matrix) 162 to order the four bits of data it receives on the SRWDL lines 151 according to the access mode of the current operation (sequential or interleave, and Column Address 0 and Column Address 1 for even or odd mode). The ordered bits from each matrix 162 are output onto another set of data lines, illustratively a set of data lines (XRWDL) 161 running in a horizontal or “X” direction. In other words, each matrix 162 may perform a 1:1 data scrambling function between the SRWD lines 151 and XRWD lines 161.

The XRWDL lines 161 are connected to the intelligent array switching logic 170, which scrambles these lines onto another set of data lines, illustratively a set of data lines (YRWDL) 171 running in the vertical or “Y” direction. Depending on the active bank 110 being written to and where it is located, upper or lower buffer stages 112_{U} or 112_{L} connects the active YRWD lines to read/write data lines (RWDL's) connected to the memory arrays 110. As illustrated, each bank may be divided into four partitions, with a particular partition selected by column address CA11 and row address RA13. For example, referring to bank 0 (the upper left bank 110₀), CA11=1 selects a partition in the upper half, CA11=0 selects a partition in the lower half, while RA13=1 selects a partition in the left side and RA13=0 selects a partition in the right side. This partitioning allows the arrays to be utilized efficiently, not only for x16 organizations, but also for x4 and x8 organizations.

In any case, the intelligent array switching logic 170 also performs a 1:1 data scrambling function at memory core frequency, writing data from the XRWD lines 161 into memory bank array through array read/write data (RWD) lines, via the YRWDs. As will be described in greater detail below, how the data is scrambled is determined by different chip organization (x4, x8 and x16). The data scrambling may also be determined based on the particular partition within a given bank being accessed (the partition may be identified by row address RA13 and column address CA11) to account for bitline twisting between banks shown in twist regions 114.

During a read access, the data propagates in the opposite direction through the intelligent array switching logic 170, near pad scrambling logic 160, and simplified pad logic 150. In other words, data may be transferred from the memory arrays 110 to the XRWD lines 161, via the intelligent array switching logic 170, to the SRWD lines 151 via the pad scrambling logic 160, and finally out to the data pads in sequence via the simplified pad logic 150. As illustrated, the near pad scrambling logic 160 may include an arrangement of switches (e.g., a matrix) 164 for each corresponding data pad, in order to reorder the data bits. As a result, the simplified pad logic 150 may simply shift the data bits out in the order it was received (at the data clock rate) without performing any complicated logic operations and without long control signal lines routed to the pads.

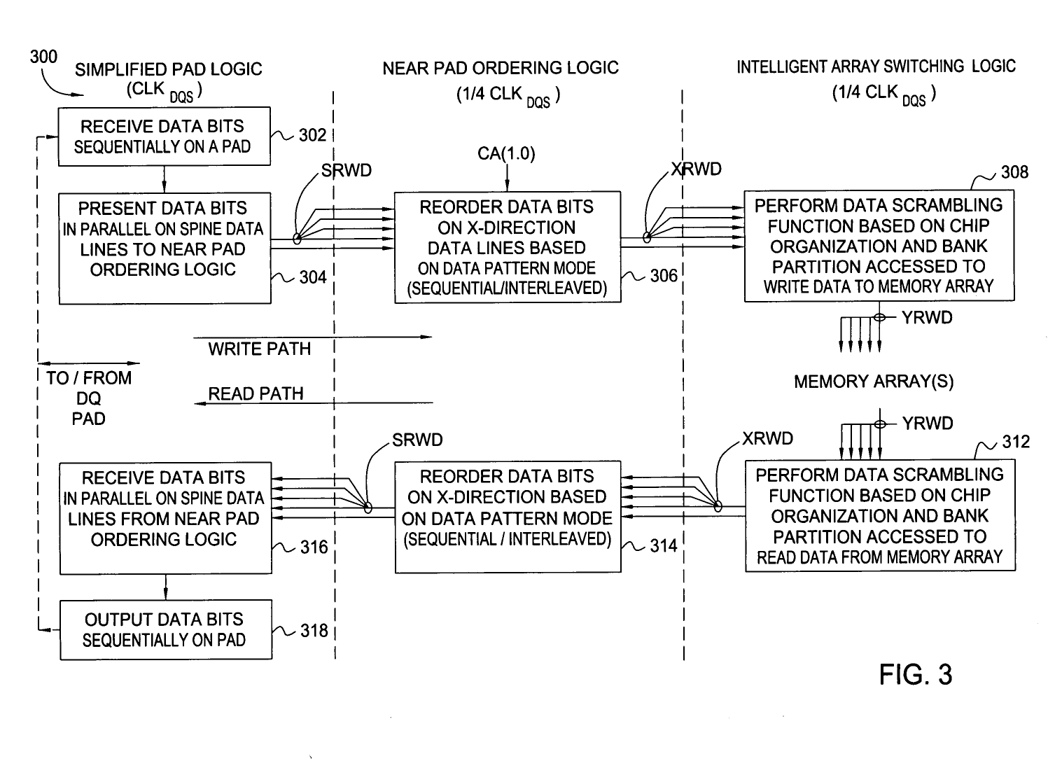

Operations performed by the by the simplified pad logic 150, near pad ordering logic 160, and intelligent array switching logic 170 during write and read accesses are summarized in FIG. 3. It should be noted that the same operations will be performed in parallel by simplified pad logic 150 for each external pad (e.g., 4, 8, or 16 pads based on the organization).

Referring first to a write access, the simplified pad logic 150 receives data bits sequentially on an external pad (at the data clock frequency). After receiving four bits of data, the simplified pad logic presents the four bits of data in parallel to the near pad ordering logic 160 on the SRWD lines 151 in the order received. At step 306, the near pad ordering logic reorders the data bits onto the XRWD lines 161 based on the data pattern mode. At step 308, the intelligent array switching logic 170 performs a data scrambling function, based on chip organization and the particular bank location being accessed relative to the twist region 114, to write data to the memory array (via the YRWD lines 171).

Referring next to FIG. 3B, during a read access, the intelligent array switching logic 170 receives read data from the array (on the YRWD lines 171) and performs a scrambling function to transfer the read data onto the XRWD lines 161, at step 312. At step 314, the near pad ordering logic 160 reorders bits onto the SRWD lines 151. At step 316, the simplified pad logic 150 receives the ordered data bits in parallel (on the SRWD lines 151) and outputs the data bits to the data pad, at step 318, in the order received.

Exemplary circuit configurations for the simplified pad logic 150, near pad ordering logic 160, and intelligent array switching logic 170 that are capable of performing the operations described above will now be described. While described separately, those skilled in the art will recognize that these logic blocks are actually switched in parallel, thus forming an efficient pipelined data path with reduced latency.

### Near Pad Ordering Logic

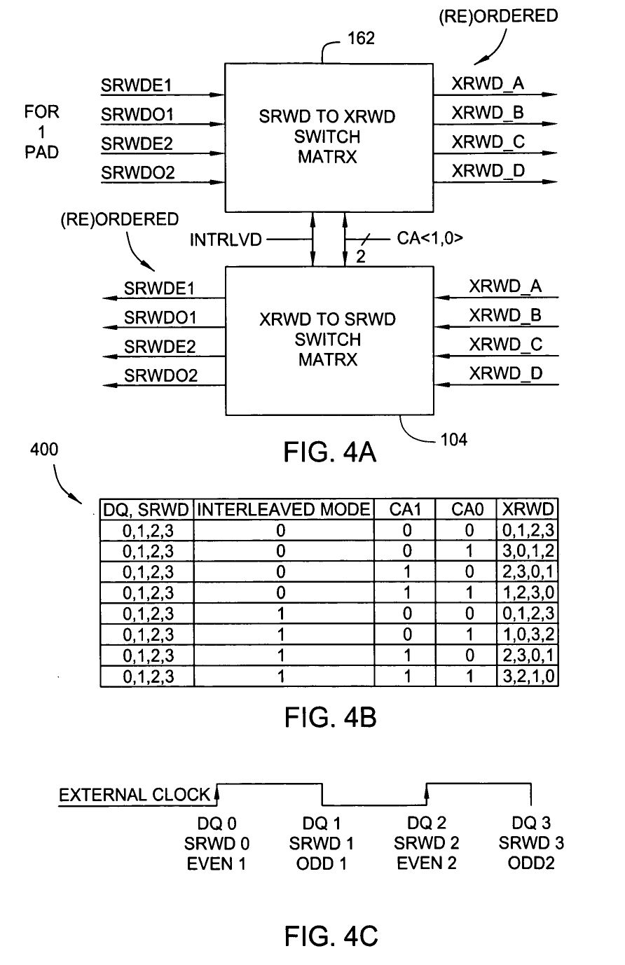

As previously described, during a write access, each stage 162 of the near pad ordering logic 160 receives four bits of data from the simplified pad logic 150 and reorders the four bits based on a specified data access mode (i.e., sequential or interleaved burst mode). In a similar manner, during a write access, each stage 164 receives four bits of data from the intelligent array switching logic 170 and reorders it (in the order in which it should be read out). FIG. 4A illustrates these read and write stages 162-164, corresponding to a single data pad, in greater detail than that provided in FIG. 2.

According to DDR-II operation, data bits are latched valid at both rising and falling edge of clock. Indexes 0, 1, 2, and 3 may be used to indicate the events where data get latched at the first clock rising edge, first clock falling edge, second clock rising edge, and second clock falling edge. As illustrated in FIG. 4C, these data bits may also be referred (in sequence) as Even1 (E1), Odd1 (O1), Even2 (E2) and Odd2 (O2) data bits. As illustrated in FIG. 4A, these Even/Odd labels may be used as postfix notation to SRWD and XRWD lines to reflect data order from and to corresponding DQ pad. During a write operation, each SRWD data line can be coupled to any one of the four XRWD lines (XRWDe1, XRWDo1, XRWDe2 and XRWDo2) via stage 162, whereas during a read sequence, each XRWD data can go to any of one of the four SRWD lines (SRWDe1, SRWDo1, SRWDe2 and SRWD02) via stage 164.

As described above, the data bits are handled sequentially at the pad level in the order received or the order it has to be driven at the output. Therefore, these indexes are needed to identity the data order. For some embodiments, the stages 162 and 164 may be configured to reorder the data in accordance with a standard data pattern mode (e.g., defined by JEDEC STANDARD JESD79-2A), which may specify sequential or interleaved burst type transfer, as well as a starting address (CA1 and CA0) within the burst. The burst type is programmable (e.g., via a mode register), while the start address is specified by a user (e.g., presented with the read/write operation).

FIG. 4B illustrates an exemplary Table 400 listing, in the far right column, how the stages 162 and 164 should reorder data based on different burst mode types and starting addresses. Also in Table 400, INTERLEAVED=1 indicates that the device is in data interleaved mode as it is defined by the JEDEC committee. Therefore, the first four entries (INTERLEAVED=0) illustrate non-interleaved/sequential type transfer modes, with different start addresses specified by column addresses (CA1 and CA0). As illustrated, even for sequential type access, if a non-zero starting address is provided, the data lines are reordered (e.g., logically shifted based on the starting address). The last four entries (INTERLEAVED=1) illustrate interleaved type transfer modes with different start addresses. Again, if a non-zero starting address is provided, the data lines are reordered, as shown.

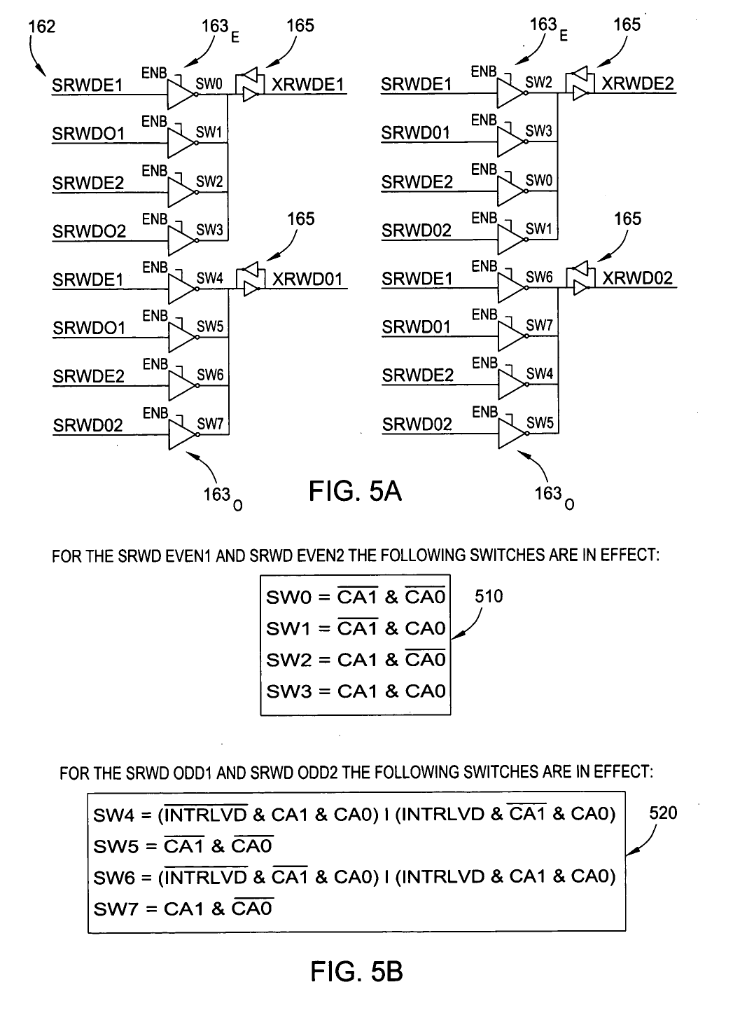

FIG. 5A illustrates an exemplary arrangement of switches 163 capable of carrying out the reordering shown in Table 400 of FIG. 4B that may be utilized in the write stage 162. As illustrated a first set of the switches 163E (labeled SW0-3) may be utilized to switch data from the SRWD lines onto the even XRWD lines (XRWDE1 and XRWDE2), while a second set of the switches 163O (labeled SW4-7) may be utilized to switch data from the SRWD lines onto the odd XRWD lines (XRWDO1 and XRWDO2). The switched output for each XRWD line may be maintained by a latch 165. FIG. 5B illustrates an exemplary truth table for controlling the switches 163, based on the column addresses CA<1,0> and an INTERLEAVED signal, in order to implement the reordering shown in Table 400.

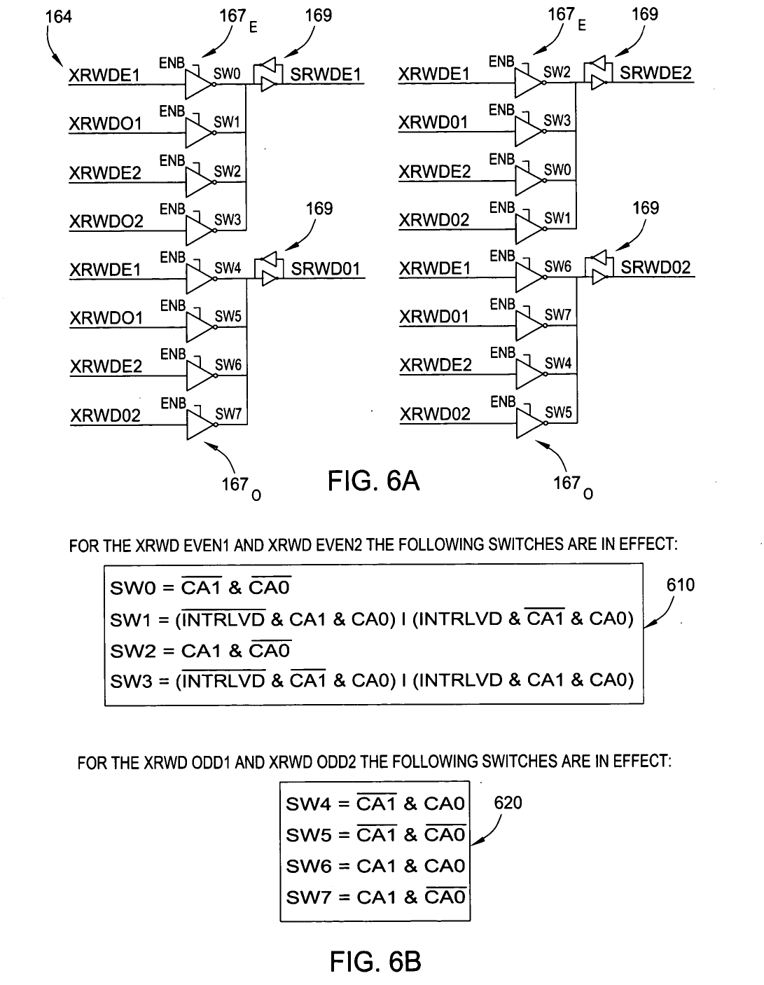

FIG. 6A illustrates a similar arrangement of switches 167 that may be utilized in the read stage 164. As illustrated a first set of the switches 167E (labeled SW0-3) may be utilized to switch data from the XRWD lines onto the even SRWD lines (SRWDE1 and SRWDE2), while a second set of the switches 167O (labeled SW4-7) may be utilized to switch data from the XRWD lines onto the odd SRWD lines (SRWDO1 and SRWDO2). The switched output for each SRWD line may be maintained by a latch 169. FIG. 6B illustrates an exemplary truth table for controlling the switches 167, based on the column addresses CA<1,0> and an INTERLEAVED signal, in order to implement the reordering shown in Table 400. As illustrated, the read and write stages 162 and 164 are essentially the same structures reused with different signals, which may result in well balanced read and write timing paths.

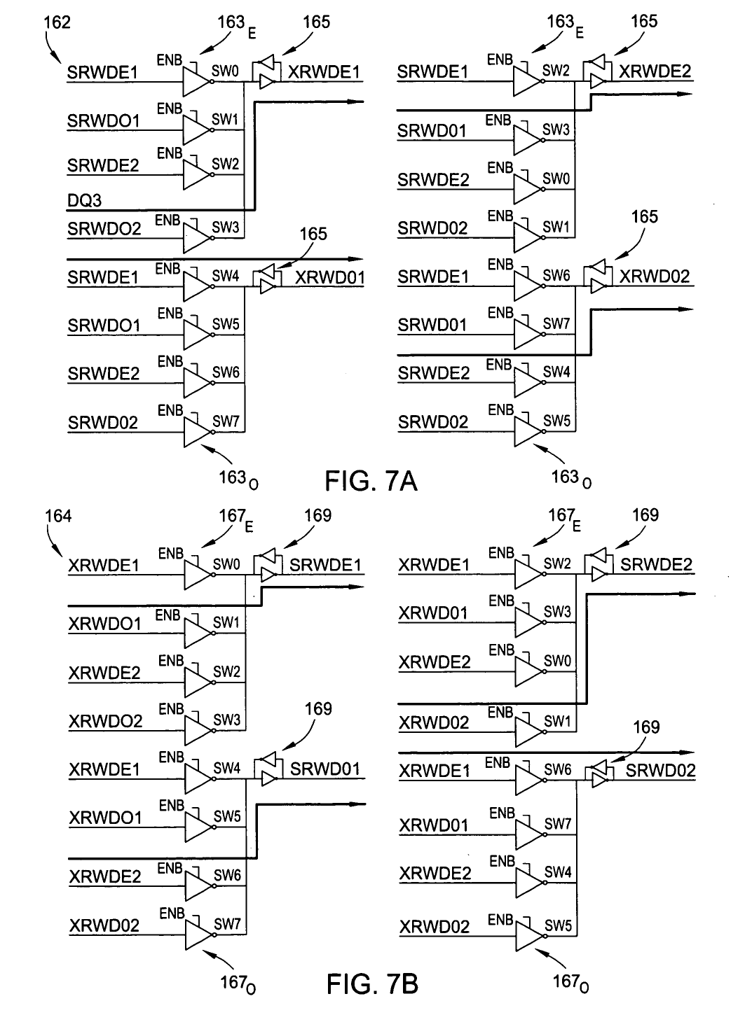

FIGS. 7A and 7B show exemplary settings for the switches 163 and 167 that illustrate how data is reordered according to Table 400. The illustrated example assumes an access mode corresponding to the fourth entry shown in Table 400, a sequential access mode with a starting address defined by CAO=1, CA1=1, which requires scrambling from indexes 0,1,2,3 (on SRWD lines) to 1,2,3,0 (on XRWD lines).

FIG. 7A illustrates the switch settings of stage 162 for a write access. Examining the truth tables 510 and 520 shown in FIG. 5B, it is seen that the example settings (INTERLEAVED=0, CA1=1, CAO=1) will result in closing switches SW3 and SW4. Closing SW3 will connect SRWDO2 (index 3) to XRWDE1 (index 0) and SRWDO1 (index 1) to XRWDE2 (index 2). Closing SW4 will connect SRWDE1 (index 0) to XRWDO1 (index 1) and SRWDE2 (index 2) to XRWDO2 (index 3), thereby correctly ordering the data lines according to the fourth entry in Table 400.

FIG. 7B illustrates the switch settings of stage 164 for a read access, with the same burst mode settings. Examining the truth tables 610 and 620 shown in FIG. 6B, it is seen that the example settings (INTERLEAVED=0, CA1=1, CA0=1) will result in closing switches SW1 and SW6. Closing SW1 will connect XRWDO1 (index 1) to SRWDE1 (index 0) and XRWDO2 (index 3) to SRWDE2 (index 2). Closing SW6 will connect XRWDE2 (index 2) to SRWDO1 (index 1) and XRWDE1 (index 0) to SRWDO2 (index 3), thereby ordering the bits in the proper order for writing them out.

Utilizing separate write and read stages 162 and 164, with identical switching structures, may help balance write and read timing. By locating these switching stages in the I/O buffer logic that connects chip center data lines (SRWD) to the data pads (DQs) may contribute to saving in the timing budget by allowing the simplified pad logic 150 to merely shift data bits in and out at the data clock frequency, without having to perform reordering operations.

### Intelligent Array Switching Logic

As previously described, in modern DRAM devices, data scrambling is often employed for various reasons, resulting in logically adjacent addresses or data locations that are not physically adjacent. Such scrambling may allow optimal geometric layout of memory cells (e.g., folding), in an effort to balance bitline and word line lengths. Scrambling may also allow array area to be optimized by sharing contacts and well areas. One type of scrambling, referred to as bitline twisting, may be employed in an effort to reduce capacitive coupling between adjacent bitline pairs.

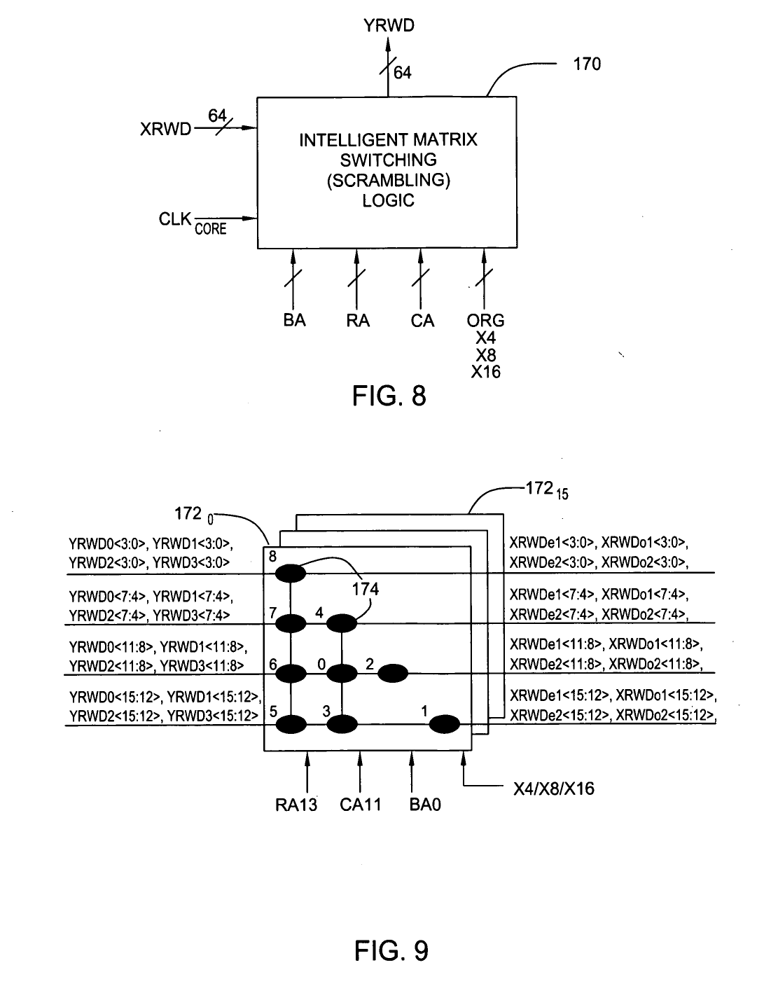

The intelligent array switching logic 170 may account for various types of scrambling, by intelligently coupling XRWD lines to YRWD lines to perform the necessary scrambling. As illustrated in FIG. 8, the switching logic 170 may operate at the core clock frequency and the scrambling operations may be controlled by bank, row, and column addresses. The scrambling operations may also be controlled by the device organization (e.g., x4, x8, or x16), which may allow the same switching logic 170 to be reused across multiple devices.

Further, the switching logic 170 may comprise an array of single matrices to simplify the design and balance timing paths. For example, as illustrated in FIG. 9, the switching logic 170 may include an array of 16 matrices 172₀₋₁₅. Each matrix 172 may have an arrangement of switches 174 configured to transfer four bits of data from the array (via YRWD lines) to one, two, or four XRWD lines (depending on the device organization). For example, in a x4 organization only pads DQ<3:0> will be used, so each matrix 172 will switch data to only one XRWD line. Similarly, in a x8 organization only pads DQ<7:0> will be used, so each matrix 172 will switch data to only two XRWD lines. In a x16 organization, all data pads DQ<15:0> will be used, so each matrix 172 will switch data to four XRWD lines.

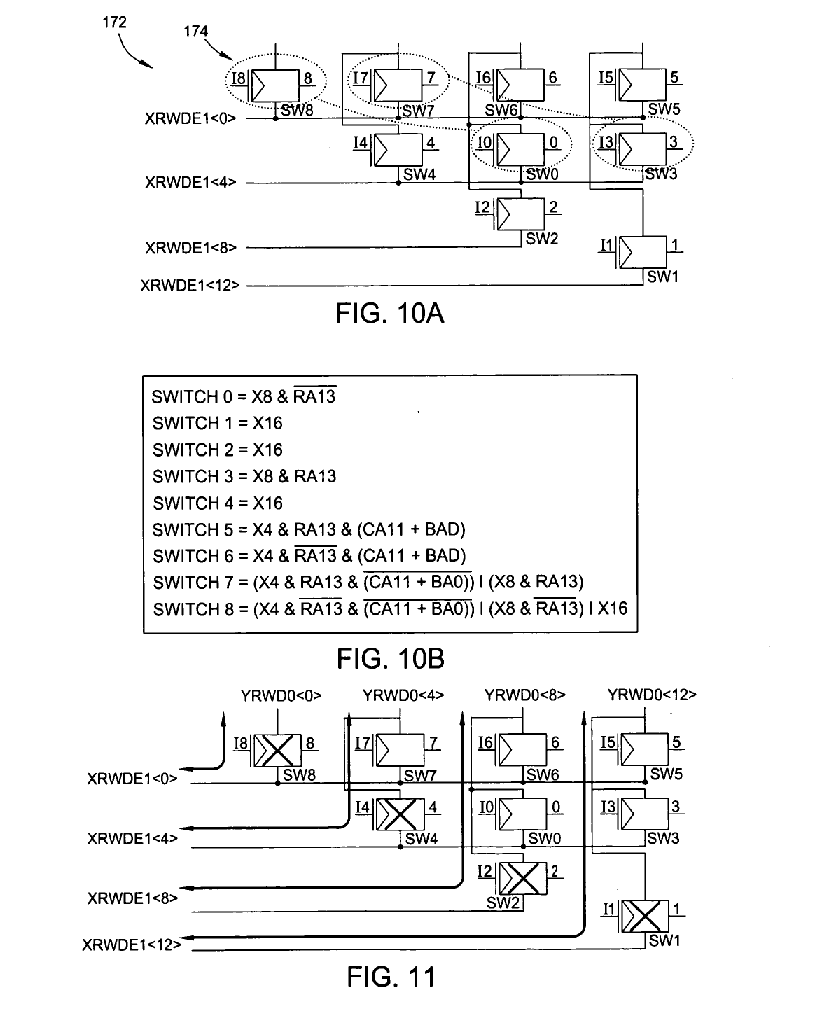

FIG. 10A illustrates a single matrix 172, as an example, with an arrangement of switches 174 configured to scramble data between “Even1” XRWD lines corresponding to data pads 0, 4, 8, and 12 and YRWD data lines for bit locations 0, 4, 8, and 12. This is just one example of a single matrix, and the switching logic 170 will include other matrices to perform similar operations to scramble data between other XRWD lines (Odd1, Even2, and Odd2) and YRWD data lines for pads 0, 4, 8, 12, as well as other sets of pads (e.g., 1-5-9-13, 2-6-10-14, 3-7-11-15).

In any case, FIG. 10B shows a truth table for setting the switches 174 based on the device organization, bank addresses BA<1,0>, row address RA13 and column address CA11. As previously described, RA13 and CA11 may select a particular partition within an active bank. Operation of the switches 174 based on signal values shown in the truth table may best be described with reference to specific examples. Decoding the matrix is also important in order to retrieve the data at the same location during a read operation.

For example, FIG. 11 illustrates the matrix 172 setting for a x16 organization. As previously described, only in this case, will all data lines (including DQ8 and DQ12) be used. Examining the truth table in FIG. 10B, it can be seen that x16 is the simplest case (in effect with no scrambling), with all diagonal switches SW1, SW2, SW4, and SW8 are turned on. As shown in FIG. 11, SW1 connects YRWDO<12> to XRWDE1<12>, SW2 connects YRWDO<8> to XRWDE1<8>, SW4 connects YRWDO<4> to XRWDE1<4>, and SW8 connects YRWDO<0>to XRWDE1<0>.

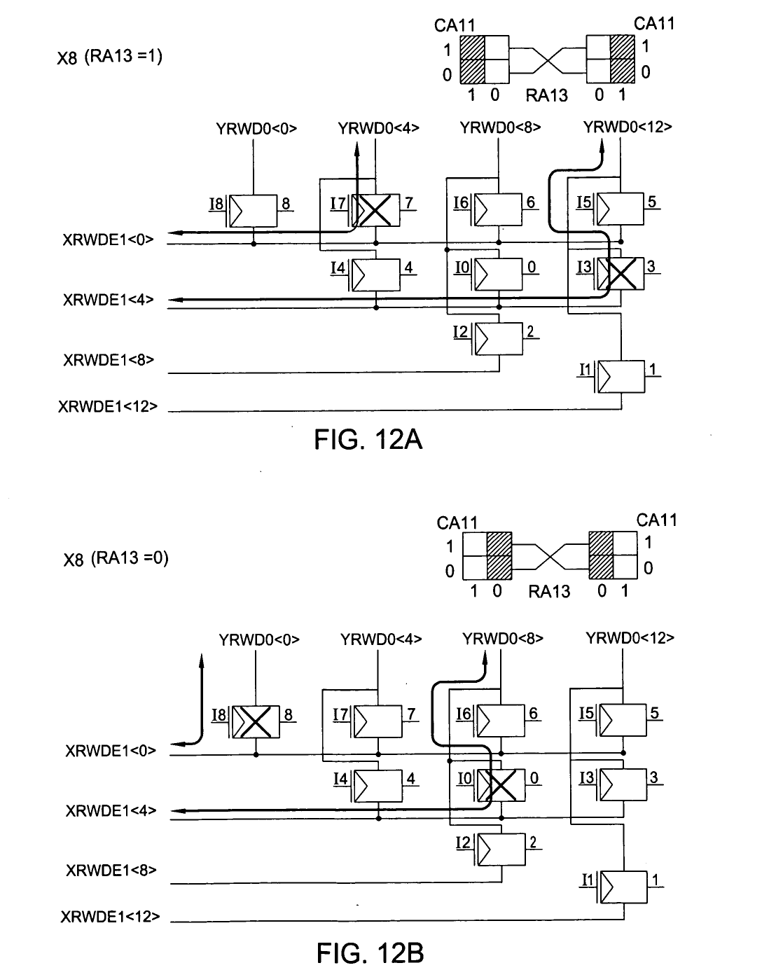

As illustrated in FIGS. 12A and 12B, two cases are available for x8 organization, with RA13 accessing either an outer or inner half (in horizontal direction) of each memory bank array. Referring to the truth table, if RA13=1, switch SW3 and switch SW7 are turned on (to access the outer bank partitions). As shown in FIG. 12A, SW3 connects YRWDO<12> to XRWDE1<4>, while SW7 connects YRWDO<4> to XRWDE1<0>. On the other hand, if RA13=0, switch SW0 and switch SW8 are turned on (to access the inner bank partitions). As shown in FIG. 12B, SW0 connects YRWDO<8> to XRWDE1<4>, while SW8 connects YRWDO<0> to XRWDE1 <0>.

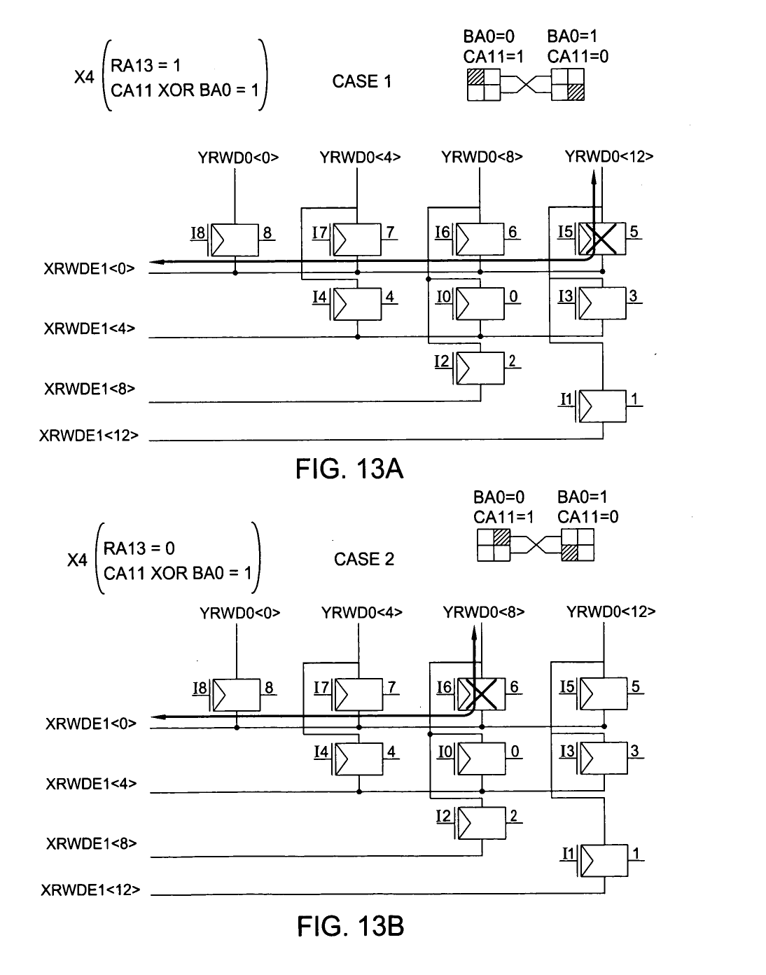

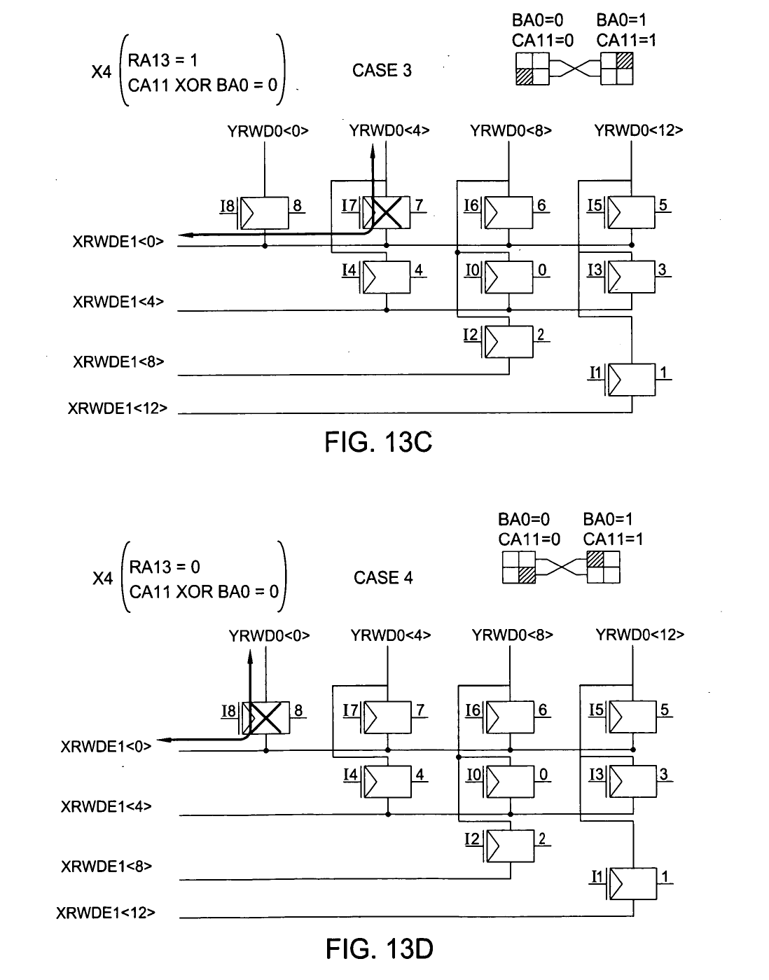

As illustrated in FIGS. 13A-D, there are four cases for X4 organization. Not only are outer or inner half partitions of the memory bank arrays controlled by RA13, but upper or lower half partitions may also be selected by CA 11. If CA11 is logic “1”, an upper half partition is accessed, while if CA11 is logic “0”, a lower half partition is accessed. In summary, each bank array is divided into four partitions: upper outer, upper inner, lower outer and lower inner. Further, due to twisting of the RWDL lines between adjacent banks (see twisting regions 114 in FIG. 2), it becomes important where to place the data on the RWDL lines to reach the target storage (correct physical location) in the memory array.

Due to the twisting, 32 bits of RWD lines flow through lower half of the left memory bank array and upper half of the right memory bank array, while the other 32 bits of RWDL flow through lower half of right memory bank array and upper half of left memory bank array. In order to properly identify the particular partitions being accessed (either upper or lower half of array section in which bank) CA11 and bank address bitO (BAO) may be logically XOR'd (e.g., utilizing the + symbol to represent XOR, CA11+BAO=“0”if both CA11 and BAO are logic “0” or logic “1”, while CA11 +BAO=“1” if CA11 and BAO are opposite logic values). As a result, in each of the four cases for x4 organization, a one quarter region in each adjacent bank is accessed.

FIG. 13A illustrates the first case, with RA13=1 and CA11+BAO=1, thereby selecting the upper outer (left) partition of the left memory bank array (BAO=0 and CA11=1) and the lower outer (right) partition of the right memory bank array (BAO=1 and CA11=0). Referring to the truth table in FIG. 10B, for this case, switch SW5 is turned on, which connects YRWDO<12> to XRWDE1<0>.

FIG. 13B illustrates the second case, with RA13=0 and CA11+BAO=1, thereby selecting the upper inner (right) partition of the left memory bank array (BAO=0 and CA11=1) and the lower inner (left) partition of the right memory bank array (BAO=1 and CA11=0). Referring to the truth table in FIG. 10B, for this case, switch SW6 is turned on, which connects YRWDO<8> to XRWDE1<0>.

FIG. 13C illustrates the third case, with RA13=1 and CA11+BAO=0, thereby selecting the lower outer (left) partition of the left memory bank array (BAO=0 and CA11=0) and the upper outer (right) partition of the right memory bank array (BAO=1 and CA11=1). Referring to the truth table in FIG. 10B, for this case, switch SW7 is turned oh, which connects YRWDO<4> to XRWDE1 <0>.

FIG. 13D illustrates the fourth case, with RA13=0 and CA11+BAO=0, thereby selecting the lower inner (right) partition of the left memory bank array (BAO=0 and CA11=0) and the upper inner (left) partition of the right memory bank array (BAO=1 and CA11=1). Referring to the truth table in FIG. 10B, for this case, switch SW8 is turned on, which connects YRWDO<0> to XRWDE1 <0>.

This overlapping switching scheme allows a minimal number of switches, which are turned on/off based on a minimum number of conditions, which may help minimize power consumption and reduce capacitive loading on the XRWD lines. Further, because SW8 would possibly turn on for all organizations, there would not be extra delay penalty for x4 components, which typically share the same mask with the x16 and x8 components. Another beneficial aspect about the illustrated scheme is that one of four RWD lines of the x4 switching scheme is placed between any two active RWD lines of the x8 switching scheme, which may reduce line to line switching coupling effect, further improving switching performance

While embodiments have been described above with specific reference to DDR-II DRAM devices, those skilled in the art will recognize that the same techniques and components may generally be used to advantage in any memory device that clocks data in at a higher clock speed than is required to process that data. Accordingly, embodiments of the present invention may also be used in (DDR-I) DRAM devices transferring two bits of data per clock cycle, as well as any later generation DDR devices (e.g., DDR-III devices transferring four bits of data per clock cycle).

Those skilled in the art will also recognize that, while one embodiment of a DRAM device utilizing separate simplified pad logic, near pad ordering logic, and intelligent array switching logic was described, other embodiments may include various other arrangements of distributed logic to achieve similar functionality. As an example, one embodiment may include separate simplified pad logic (operating at the data clock frequency) and a single logic unit (operating at the lower memory core clock frequency) that handles both the reordering and scrambling functions performed by the separate near pad ordering logic and intelligent array switching logic. Still another embodiment may integrate the reordering with the pad logic (operating both at the data clock frequency) and utilize intelligent switching array logic (operating at the lower memory core clock frequency) to perform the scrambling functions described herein.

### CONCLUSION

Embodiments of the present invention may be utilized to reduce the data path speed stress of DRAM devices with high data clock frequencies. By separating high speed pad logic from switching logic that may perform various other logic functions (e.g., reordering and scrambling logic), the switching logic performing those functions may be allowed to operate at a lower clock frequency (e.g., ½ the external clock frequency or ¼ the data frequency), which may relax associated timing requirements and improve latency due to savings in the transition time of the data from memory arrays to the DQ pads and vice versa. By utilizing optimized switch arrangements, balanced delay times across read and write paths, as well as across different device organizations, may also be achieved.

While the foregoing is directed to embodiments of the present invention, other and further embodiments of the invention may be devised without departing from the basic scope thereof, and the scope thereof is determined by the claims that follow.

What is claimed is:

1. A memory device, comprising:
one or more memory arrays;
a plurality of data pads;
an input/output (I/O) buffer stage with pad logic for receiving bits of data to be written to the memory arrays and outputting bits of data sequentially on the plurality of pads, wherein N bits of data are received or transferred in a single cycle of an external clock signal; and
reordering logic driven by a core clock signal having a frequency one half that of the external clock signal or less and configured to reorder the N bits of data received on each data pad based at least in part on a burst transfer type prior to writing the N bits to the one or more memory arrays or prior to outputting the N bits sequentially on the plurality of pads.

2. The memory device of claim 1, wherein N=4.

3. The memory device of claim 1, wherein the reordering logic comprises a plurality of stages, each configured to reorder N-bits of data received from or to be output by a corresponding data pad.

4. The memory device of claim 3, wherein each stage comprises:
a write switch matrix configured to reorder N bits of data received from corresponding pad logic in parallel on a first set of data lines and present the reordered N bits on a second set of data lines to be written to the memory arrays; and
a read switch matrix configured to reorder N bits of data received on the second set of data lines and present the reordered N bits to corresponding pad logic on the first set of data lines to be output sequentially on a coresponding data pad.

5. The memory device of claim 4, wherein the write switch matrices and read switch matrices are substantially identical in structure.

6. A memory device, comprising:
one or more memory arrays;
a plurality of data pads; and
a pipelined data path for transferring data between the one or more memory arrays and the plurality of pads comprising an input/output (I/O) buffer stage with pad logic for buffering bits of data exchanged sequentially between the data pads and an external device in conjunction with a data clock signal and reordering logic for reordering bits of data received by or to be output by the pad logic in conjunction with a core clock signal having a frequency one quarter that of the data clock signal or less.

7. The memory device of claim 6, wherein the pipelined data path further comprises scrambling logic for scrambling, based at least in part on physical locations of targeted memory cells, reordered bits of data prior to writing them to the memory arrays.

8. The memory device of claim 7, wherein the scrambling logic and reordering logic are switched in parallel.

9. A memory device capable of transferring multiple bits on each of a plurality of data pads in a single external clock signal, comprising:
one or more memory arrays; and
reordering logic driven by a core clock signal having a frequency one half that of the external clock signal or less and configured to reorder bits of data received sequentially on the data pads to be written to the memory arrays and to reorder bits of data read from the memory arrays to be output sequentially on the data pads.

10. The memory device of claim 9, wherein:
the reordering logic is integrated with pad logic in an input/output (I/O) buffering structure; and
the pad logic is driven by a data clock signal having a frequency at least twice the frequency of the external clock signal.

11. The memory device of claim 9, wherein the reordering logic is configured to reorder bits based on a burst transfer type and burst start address.

12. A method of exchanging data with a memory device, comprising:
receiving N bits of data on each of a plurality of data pads within a single cycle of an external clock signal; and
reordering the N bits of data in conjunction with an internal core clock signal having a frequency one half or less than that of the external clock signal.

13. The method of claim 12, wherein reordering the bits comprises reordering the bits based, at least in part, on a burst transfer type.

14. The method of claim 12, further comprising presenting reordered bits on a first set of data lines oriented in a first direction to be scrambled onto a second set of data lines oriented in a second direction substantially perpendicular to the first direction.

15. The method of claim 14, further comprising:
reading bits of data from the memory arrays on the second set of data lines;
scrambling the bits of data onto the first set of data lines;
reordering the scrambled bits of data; and
outputting N reordered bits sequentially on each of the data pads.

16. A method of exchanging data between data pads and one or more memory arrays, comprising, during a write operation:
generating, from an external clock signal, a core clock signal having a lower frequency than the external clock signal;
sequentially receiving multiple bits of data to be written to the memory arrays on the data pads in a single cycle of the external clock signal; and
reordering, in conjunction with the core clock signal, the sequentially received bits of data prior to being written to the memory arrays or prior to being output on the data pads.

17. The method of claim 16, wherein the frequency of the external clock signal is at least twice the frequency of the core clock signal.

18. The method of claim 16, comprising receiving at least four bits of data sequentially on each pad in a single cycle of the external clock signal.

19. The method of claim 18, further comprising generating a data clock signal, wherein a frequency of the data clock signal is at least four times the frequency of the external clock signal.

20. The method of claim 16, further comprising, during a read operation:
reading bits of data from the memory arrays;
reordering the bits of data read from the memory arrays; and
outputting N reordered bits sequentially on each of the data pads.
